(19) United States
(12) Patent Application Publication
(10) Pub. No.: US 2013/0173188 A1
(43) Pub. Date: Jul. 4, 2013

(54) Probabilistic Measurement and Verification

(71) Applicants: Bradley Kayton, Hollis, NH (US); Jon Rappaport, Mathews, NC (US); Jacob Stuart Michael Beal, Somerville, MA (US)

(72) Inventors: Bradley Kayton, Hollis, NH (US); Jon Rappaport, Mathews, NC (US); Jacob Stuart Michael Beal, Somerville, MA (US)

(21) Appl. No.: 13/548,802

(22) Filed: Jul. 13, 2012

Related U.S. Application Data
(60) Provisional application No. 61/507,586, filed on Jul. 13, 2011.

(51) Int. Cl. G01R 21/00

(52) U.S. Cl. CPC G01R 21/00
USPC 702/60

(57) ABSTRACT

The present invention is directed to a system and method for quantifying, measuring and verifying the results of demand side energy management programs in a smart grid by the selection of a smart grid device from the universe of smart grid devices participating in the demand side energy management program by a selecting energy collection server and collecting data from the selected smart grid device in order to reduce the load on the network. An agent resident on the selected smart grid device transmits data to the selecting energy collection server which utilizes the data to verify the demand side energy management program.

### CROSS-REFERENCE TO RELATED APPLICATIONS

The present application is a continuation application of U.S. provisional patent application Ser. No. 61/507,586, filed Jul. 13, 2011, for Probabilistic Measurement and Verification, by Bradley Kayton and Jon Rappaport, included by reference herein and for which benefit of the priority date is hereby claimed.

### FEDERALLY SPONSORED RESEARCH

Not applicable.

### SEQUENCE LISTING OR PROGRAM

Not applicable.

### FIELD OF INVENTION

The present invention relates to electrical energy systems and, more particularly, to smart electrical grids.

### BACKGROUND OF THE INVENTION

Increasingly, energy efficiency programs are being considered energy resources, like generation, and consequently are built into integrated resource plans to meet forecasted load. The challenge is that most are unmetered resources. The impact the programs have in aggregate on meeting energy demand must be ascertained through evaluation, measurement and verification.

Existing energy systems are plagued by high variability in demand for power and the lack of effective control over the demand. For example, peak electrical consumption (in terms of wattage) is much higher than average consumption, but the total duration of peak consumption is relatively short. It can be costly to maintain the surge capacity that is only needed during peak consumption periods. As a result, utility companies often impose brown-outs and/or black-outs when capacity is insufficient. This practice has many negative impacts on the residents and businesses in the service area.

Some research has been done in recent years to develop more cost effective and less intrusive methods for easing the strains on existing energy systems. For example, studies have shown that there is a high level of flexibility in actual consumer requirements, and therefore it is possible in theory to reduce peak consumption without depriving consumers of energy they are unwilling to give up.

One conventional approach is to encourage consumers to conserve energy voluntarily by increasing their awareness of energy consumption. For example, studies have shown that information about energy consumption of consumers relative to their neighbors can cause high consumers to dramatically reduce their consumption. Also, studies conducted in California showed that consumers given a “mood ring” that indicates in real time the stress on the power grid dramatically reduced their peak-time consumption.

Another conventional approach is to use energy pricing, either in real or virtual currency, to gauge each consumer's willingness to reduce consumption. In these so-called market-based systems, the price of energy is allowed to fluctuate in real time based on actual demand, which provides an economic incentive for consumers to reduce consumption when the actual demand is high. The rationale behind these systems is that the price a consumer is willing to pay for energy is inversely related to the consumer's willingness to reduce energy consumption, so that a consumer who is more willing to reduce energy consumption will do so at a lower price point compared to another consumer who is less willing to reduce energy consumption. Thus, as the market finds equilibrium, the system approaches a desired state where each consumer reduces energy consumption only to the extent he is willing.

Conventional systems have also been developed to control energy demand related to heating and/or cooling in a building. Typically, these systems employ a centralized architecture where a central controller collects information from various sources and provides control signals to heating and/or cooling units based on the collected information.

New methods of demand-response are desirable to overcome the shortcomings of conventional systems. However, utilities are reluctant to undergo significant changes, such as implementing new methods of demand-response management, without significant corroboration of benefit and palpable sense of operation. Measurement and verification (M&V) of curtailed energy (energy saved when needed by the electric utility) is difficult to achieve accurately but important if energy curtailment is to have any sort of market-based pricing, which is the current trend in certain energy programs, or when trying to determine customer rebates. Moreover, in more advanced systems, 100% of measured devices returning the energy curtailed information in real-time is often not viable over certain networks. Historically, even cruder models of energy measurement and verification have been used.

Current measurement and verifications systems generally look at baseline modes, from one day to the next. For example, using the 90/10 rule, a system will look at the last week, then take a 10% rating to the current day, just before and that's their answer.

Other than the 90/10 rule, measurements can be taken directly from the device itself, and you can also look into the meter to measure the flows of the before and after, so it's a 1 to 1 correlation. That means that all that data needs to be uploaded over the network on the back call channel to eventually be time stamped, put into data management system, and archived somewhere else for verification.

On one end of the spectrum, there are very crude measurement and verification systems comprising of taking a measurement before and after an event, with some kind of weighted average or previous baseline. This approach suffers from being overly broad and nonspecific.

On the other end of the spectrum, there are very specific measurement systems that create massive amounts of data. This approach suffers from excessive computation and time required to process the data.

It would be advantageous to provide a system to quantify results of a demand-response operation with sufficient specificity and in a timely manner.

It would also be advantageous to provide a system to use real measurement and verification to calibrate virtual measurement and verification.

It would further be advantageous to provide a system to verify arbitrary strategies from arbitrary vendors.

It would further be advantageous to provide a system to quantify results of a demand-response operation without having to transmit data relevant from each device over the network.

### SUMMARY OF THE INVENTION

In accordance with the present invention, there is provided a method and system for quantifying, measuring and verifying the results of demand-response operations in a smart grid.

### BRIEF DESCRIPTION OF THE DRAWINGS

A complete understanding of the present invention may be obtained by reference to the accompanying drawings, when considered in conjunction with the subsequent, detailed description, in which:

FIG. 1 is a block diagram of various functional components participating in a demand response call.

FIG. 2 is a block diagram of various functional components of a probabilistic measurement and verification system.

### DESCRIPTION OF THE PREFERRED EMBODIMENT

Before the invention is described in further detail, it is to be understood that the invention is not limited to the particular embodiments described, as such may, of course, vary. It is also to be understood that the terminology used herein is for the purpose of describing particular embodiments only, and not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range is encompassed with the invention. The upper and lower limits of these smaller ranges may independently be included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, a limited number of the exemplary methods and materials are described herein.

It must be noted that as used herein and in the appended claims, the singular forms “a”, “an”, and “the” include plural referents unless the context clearly dictates otherwise.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, if dates of publication are provided, they may be different from the actual publication dates and may need to be confirmed independently.

The present invention uses a more wide scale approach without the necessity of creating all the data associated with measuring every single end point device. In one embodiment, the system takes a statistical sampling based on spatial probabilistic computing with a mechanism that can send better commands using a distributed probabilistic computing system.

An advantage of such a simple mechanism is that not all data is sent back to the server, but rather a sampling percentage such as 10% or 20%. With a rating mechanism, a method is provided to validate a market, and also reduce the traffic on the network. With a 10% sample, if 100% is accurate, then a positive reading is determined. If the sample is 50% accurate, then a negative reading is determined. In other embodiments, you can adjust the system, provide an ongoing feedback loop, take a larger sampling, or investigate what's going on with the program.

The architecture comprises the basic loop including devices, a server, and communications. In one embodiment, the system measurement verification processes a hierarchy tree of data, from the device, the metered data, metered data that's specifically time stamped, or more broadly a moving average below that time stamp, before or after. The data is obtained from the home, from the energy gateway, or directly from the device. Whether its metered data or whether its asynchronous based on the recorded data that technically could be the energy gateway, or more likely be embedded into meter data management from a probabilistic standpoint.

In one embodiment, not every single data point is taken; the system takes the average of a randomized sub-sampling to process. Micro loads require the ability to constantly audit the entire system, aggregate load relieve this constraint.

In one embodiment, a micro audit is used to statistically verify the whole, or a larger unit. Verification enables the processing of a lot less data and to get the same results. The system can process a complete aggregate of all the loads. In one embodiment, the system can be applied to obtain virtual power and to verify each individual micro load. The system can address the overall load, bringing it down to a specific number of pennies per kW/hr to enable a virtual power market. It is currently difficult monetizing micro loads, and obviously difficult to do so with the current mechanisms being used today for M&V.

The current costs of tracking micro loads are too expensive to justify them. The present invention can get a sufficient quality of data that enables consumers to be rewarded for those micro load savings via a M&V system that stands up to scrutiny to justify payments and rebates.

In one embodiment of the invention, results for individual users are tiered. The system places users in specific tiers and gives them a rebate based on that tier.

There are different ways to do measurement verification, whether it's real time or whether it's synchronous or asynchronous, and in all cases, with a randomized distributed and probabilistic methodology of viewing the data, the same results can be obtained in terms of having to get an audit for the system, without all of the overhead involved with trying to record all the data, send all the data, query all the data, and store all the data.

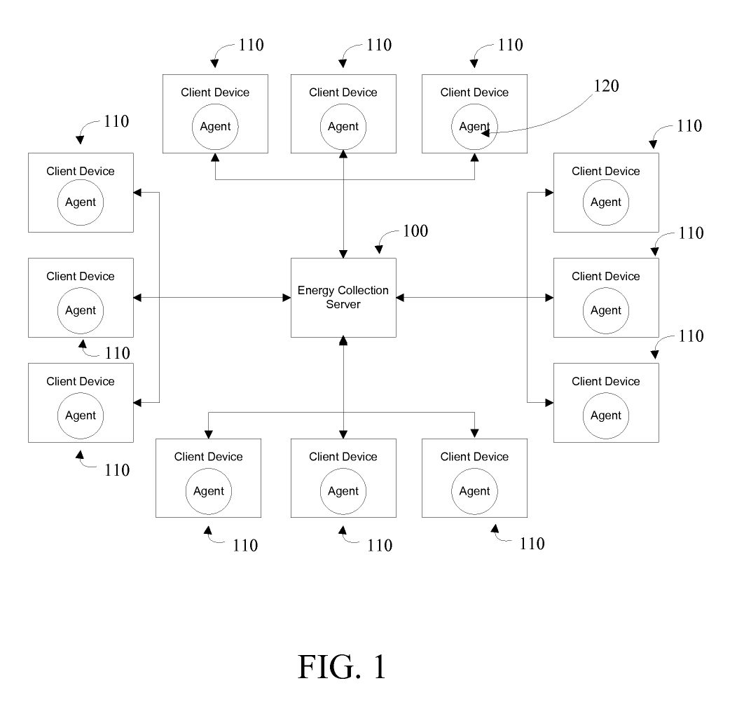

With reference now to FIG. 1, energy collection server 100 collects data from numerous agents 120 embedded in each of the client devices 110 in the system. In the present instance, twelve client devices are shown. Each agent 120 measures or estimates energy usage of the host client device 110, and transmits that data to the energy collection server 100 in response to a request from the energy collection server 100, or based on a pre-set schedule.

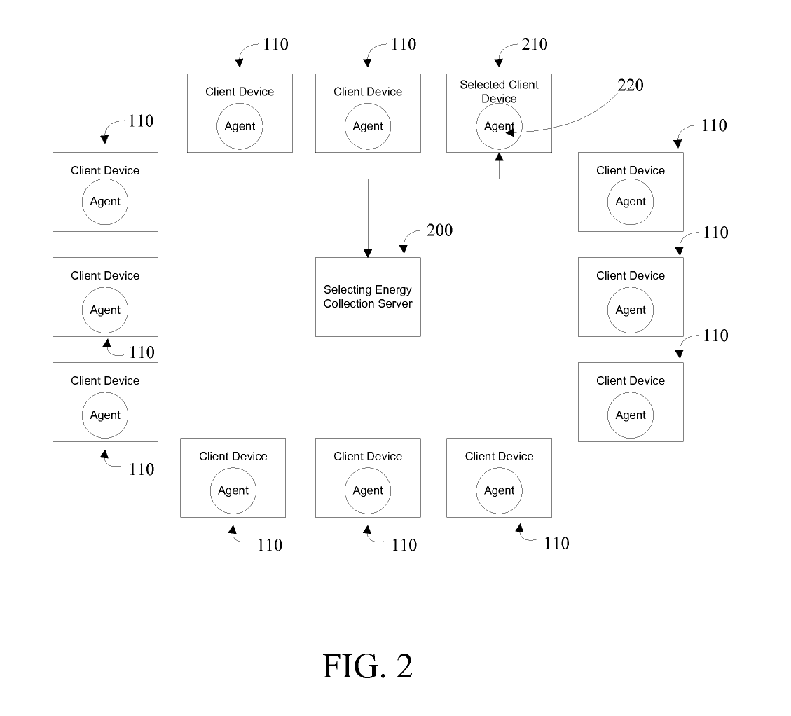

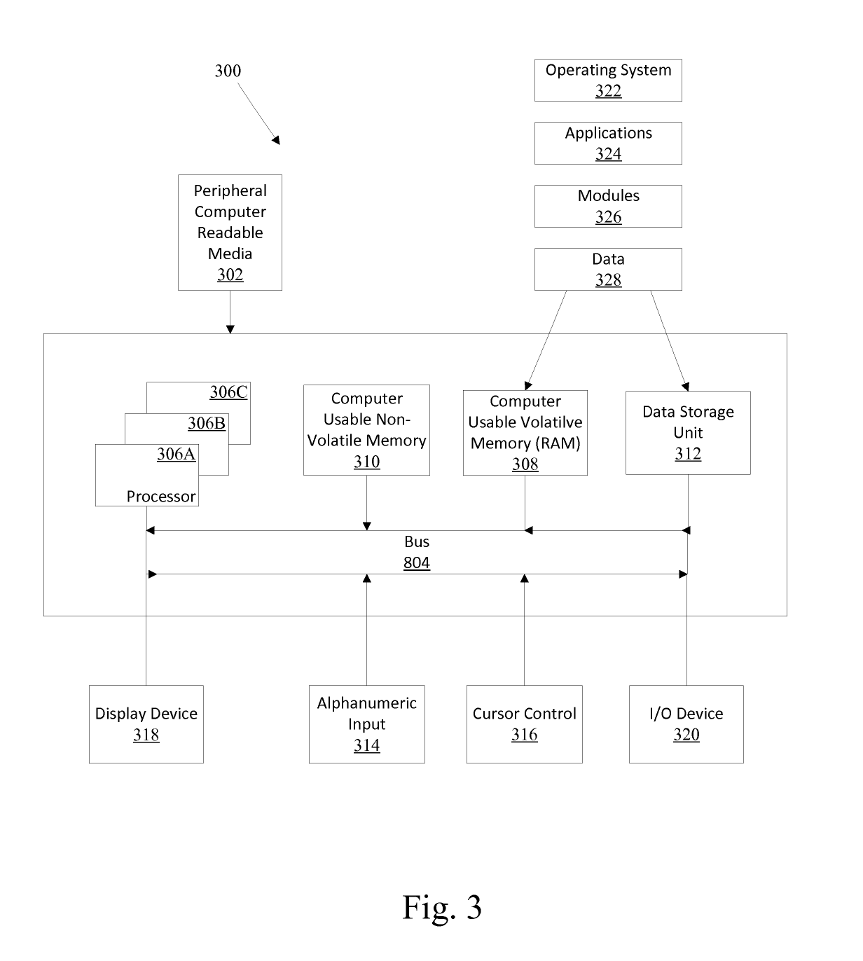

With reference now to FIG. 2, selecting energy collection server 200 collects data from selected agent 220 embedded in selected client device 210 in the system. In the present instance, one selected client device 210 is shown, which represents approximately 8% of the client devices 110 shown in FIG. 1. Since only a fraction of the potential selected client devices are transmitting data to the selecting energy collection server 200, network traffic is significantly reduced. The selected agent 220 measures or estimates energy usage of the host client device 210, and transmits that data to the selecting energy collection server 200 in response to a request from the selecting energy collection server 200, or based on a pre-set schedule. In one embodiment of the present invention, the selecting energy collection server 200 selects a selected client device 210 by making an assessment of where there is the least network traffic or congestion. In another embodiment of the present invention, the selecting energy collection server 100 randomly selects the selected client device 210 from the universe of client devices 110. In another embodiment of the present invention, the selecting energy collection server 100 algorithmically selects the selected client device 210 from the universe of client devices 110.

### Example Computing System

With reference now to FIG. 3, portions of the technology for providing computer-readable and computer-executable instructions that reside, for example, in or on computer-usable media of a computer system. That is, FIG. 3 illustrates one example of a type of computer that can be used to implement one embodiment of the present technology.

Although computer system 300 of FIG. 3 is an example of one embodiment, the present technology is well suited for operation on or with a number of different computer systems including general purpose networked computer systems, embedded computer systems, routers, switches, server devices, user devices, various intermediate devices/artifacts, standalone computer systems, mobile phones, personal data assistants, and the like.

In one embodiment, computer system 300 of FIG. 3 includes peripheral computer readable media 302 such as, for example, a floppy disk, a compact disc, and the like coupled thereto.

Computer system 300 of FIG. 3 also includes an address/data bus 304 for communicating information, and a processor 306A coupled to bus 304 for processing information and instructions. In one embodiment, computer system 300 includes a multi-processor environment in which a plurality of processors 306A, 306B, and 306C are present. Conversely, computer system 300 is also well suited to having a single processor such as, for example, processor 306A. Processors 306A, 306B, and 306C may be any of various types of microprocessors. Computer system 300 also includes data storage features such as a computer usable volatile memory 308, e.g. random access memory (RAM), coupled to bus 304 for storing information and instructions for processors 306A, 306B, and 306C.

Computer system 300 also includes computer usable non-volatile memory 310, e.g. read only memory (ROM), coupled to bus 304 for storing static information and instructions for processors 306A, 306B, and 306C. Also present in computer system 300 is a data storage unit 312 (e.g., a magnetic or optical disk and disk drive) coupled to bus 304 for storing information and instructions. Computer system 300 also includes an optional alpha-numeric input device 314 including alpha-numeric and function keys coupled to bus 304 for communicating information and command selections to processor 306A or processors 306A, 306B, and 306C. Computer system 300 also includes an optional cursor control device 316 coupled to bus 304 for communicating user input information and command selections to processor 306A or processors 306A, 306B, and 306C. In one embodiment, an optional display device 318 is coupled to bus 304 for displaying information.

Referring still to FIG. 3, optional display device 318 of FIG. 3 may be a liquid crystal device, cathode ray tube, plasma display device or other display device suitable for creating graphic images and alpha-numeric characters recognizable to a user. Optional cursor control device 316 allows the computer user to dynamically signal the movement of a visible symbol (cursor) on a display screen of display device 318. Implementations of cursor control device 316 include a trackball, mouse, touch pad, joystick or special keys on alphanumeric input device 314 capable of signaling movement of a given direction or manner of displacement. Alternatively, in one embodiment, the cursor can be directed and/or activated via input from alpha-numeric input device 314 using special keys and key sequence commands or other means such as, for example, voice commands.

Computer system 300 also includes an I/O device 320 for coupling computer system 300 with external entities. In one embodiment, I/O device 320 is a modem for enabling wired or wireless communications between computer system 300 and an external network such as, but not limited to, the Internet. Referring still to FIG. 3, various other components are depicted for computer system 300. Specifically, when present, an operating system 322, applications 324, modules 326, and data 328 are shown as typically residing in one or some combination of computer usable volatile memory 308, e.g. random access memory (RAM), and data storage unit 312. However, in an alternate embodiment, operating system 322 may be stored in another location such as on a network or on a flash drive. Further, operating system 322 may be accessed from a remote location via, for example, a coupling to the internet. In one embodiment, the present technology is stored as an application 324 or module 326 in memory locations within RAM 308 and memory areas within data storage unit 312.

The present technology may be described in the general context of computer-executable instructions stored on computer readable medium that may be executed by a computer. However, one embodiment of the present technology may also utilize a distributed computing environment where tasks are performed remotely by devices linked through a communications network.

It should be further understood that the examples and embodiments pertaining to the systems and methods disclosed herein are not meant to limit the possible implementations of the present technology. Further, although the subject matter has been described in a language specific to structural features and/or methodological acts, it is to be understood that the subject matter defined in the appended claims is not necessarily limited to the specific features or acts described above. Rather, the specific features and acts described above are disclosed as example forms of implementing the Claims.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

What is claimed is:

1. A system for measuring and verifying energy curtailment in a demand side energy management program, said system comprising:
a selecting energy collection server;
at least one selected smart grid device;
an agent hosted in said at least one selected smart grid device capable of transmitting data to said selecting energy collection server;
wherein each said at least one selected smart grid device is selected from a universe of smart grid devices in a network participating in said demand side energy management program by said selecting energy collection server in order to minimize the load on said network; and
wherein said agent transmits data pertaining to the energy usage of said at least one smart grid device to said selecting energy collection server; and
wherein said selecting energy collection server utilizes said data to verify said energy curtailment in said energy management program.

2. The system of claim 1, further comprising at least one virtual smart grid device located in said network wherein
a. said selecting energy collection server utilizes said data to calibrate measurement and verification of said virtual smart grid devices.

3. The system of claim 1, wherein said network comprises the public Internet.

4. The system of claim 1, wherein said network comprises an AMI network
a. The system of claim 1, wherein said selecting energy collection server can verify arbitrary demand side energy management programs.

5. The system of claim 1, wherein said agent is hosted in a Home Area Network gateway, an Internet gateway, or a smart meter and is communicatively connected to said selected smart grid device.

6. The system of claim 1, wherein said agent transmits data comprising a randomized sub-sampling of said host smart grid device's energy usage to said selecting energy collection server.

7. The system of claim 1, wherein said agent transmits data to said selecting energy collection server in real time.

8. The system of claim 1, wherein said agent transmits data to said selecting energy collection server asynchronously.

9. A method for measuring and verifying energy curtailment in a demand side energy management program, said method comprising:
selecting at least one smart grid device from a universe of smart grid devices in a network participating in said demand side energy management program;
receiving data on the energy usage of said at least one smart grid device from an agent hosted by said at least one smart grid device;
analyzing said data to verify said energy curtailment of said demand side energy management program;
wherein the selection of said at least one smart grid device occurs by an evaluation of the universe of smart grid devices by a selecting energy collection server determining the most efficient source of said data.

10. The method of claim 9, further comprising utilizing said data to calibrate measurement and verification a virtual smart grid devices located in said network.

11. The method of claim 9, further comprising transmitting said data over the public Internet.

12. The method of claim 9, further comprising transmitting said data over an AMI network.

13. The method of claim 9, wherein said agent is hosted in a Home Area Network gateway, an Internet gateway, or a smart meter and is communicatively connected to said selected smart grid device.

14. The method of claim 9, further comprising transmitting data comprising a randomized sub-sampling of said host smart grid device's energy usage to said selecting energy collection server.

15. The method of claim 9, further comprising transmitting said data in real time.

16. The method of claim 9, further comprising transmitting said data asynchronously.

17. A non-transitory computer readable media to store programming instructions for measuring and verifying a demand side energy management program, the non-transitory computer readable media comprising:
programming instructions for selecting at least one smart grid device from a universe of smart grid devices in a network participating in said demand side energy management program;
programming instructions for receiving data on the energy usage of said at least one smart grid device from an agent hosted by said at least one smart grid device;
programming instructions for analyzing said data to verify said energy curtailment of said demand side energy management program;
wherein the selection of said at least one smart grid device occurs by an evaluation of the universe of smart grid devices by a selecting energy collection server determining the most efficient source of said data.

18. The non-transitory computer readable media as recited in claim 17, further comprising utilizing said data to calibrate measurement and verification a virtual smart grid devices located in said network.

19. The non-transitory computer readable media as recited in claim 17, further comprising transmitting said data over the public Internet.

20. The non-transitory computer readable media as recited in claim 17, further comprising transmitting said data over an AMI network.

21. The non-transitory computer readable media as recited in claim 17, wherein said agent is hosted in a Home Area Network gateway, an Internet gateway, or a smart meter and is communicatively connected to said selected smart grid device.

22. The non-transitory computer readable media as recited in claim 17, further comprising transmitting data comprising a randomized sub-sampling of said host smart grid device's energy usage to said selecting energy collection server.

23. The non-transitory computer readable media as recited in claim 17, further comprising transmitting said data in real time.

24. The non-transitory computer readable media as recited in claim 17, comprising transmitting said data asynchronously.
